(19) United States
(12) Patent Application Publication
(10) Pub. No.: US 2003/0158990 A1
(43) Pub. Date: Aug. 21, 2003

(54) Method and apparatus of disabling the pull-up on a USB type of data line

(76) Inventors: Gregory M. Allen, Layton, UT (US); Don I. Jacob, Kaysville, UT (US); Michael C. Burnside, South Weber, UT (US)

Correspondence Address: Parsons Behle & Latimer, Suite 1800, 201 South Main Street, Post Office Box 45898, Salt Lake City, UT, 84111-2218, US

(21) Appl. No.: 10/021,565

(22) Filed: Dec. 11, 2001

(51) Int. Cl. G06F 13/14; H03K 17/16; H03B 1/00

(52) U.S. Cl. 710/305; 326/30; 327/108

(57) ABSTRACT

A method and apparatus for enabling and disabling a pull-up resistor connected to a data line of a universal serial bus is provided for universal serial bus devices that are provided with an external power source. A transistor is interconnected between VBUS of the universal serial bus connection and the input of an integrated circuit such that the voltage on the input of the integrated circuit is proportional to the voltage on VBUS. Thus, when VBUS is not present the pull-up resistor on the data line is disabled and subsequently enabled when VBUS exceeds a predetermined threshold.

### BACKGROUND

1. Field of the Invention

The present invention relates generally to Universal Serial Bus (USB) devices. More particularly, the present invention relates to a method and apparatus for disabling the pull-up resistor on a USB device when VBUS is not present to prevent a host computer from locking up or freezing. Such a condition may occur if a voltage is provided on the D+ or D-lines when VBUS is not present.

2. Description of the Prior Art

Universal Serial Bus (USB) is a specification for connecting peripheral devices to a personal computer. It was developed by various computer hardware and software companies to provide a universal connection of devices while providing relatively high data transfer speed. USB 1.1 provides two types of data transfer rate, one at 1.5 Mbps and one at 12 Mbps. In addition, the USB is capable of providing a maximum of 500 mA of current to devices attached on the bus. Furthermore, USB 1.1 was designed to meet Microsoft Corporations Plug and Play specification to allow users to hot swap devices without lengthy installation procedures and computer rebooting. With Plug and Play devices on a WINDOWS operating system, the operating system can detect the device being connected and automatically install the appropriate drivers, if desired.

There are three basic components of USB technology. The first is the host which is actually the central point for all connections, serving as the point at which all communication between the hardware occurs. The host controller (i.e., the hardware implementation of the host) may be integrated into the motherboard of the computer or provided on other USB add-on devices, such as a card.

The second component is the hub. The hub allows multiple USB devices to be connected to a single output of the USB host controller. Often times, the hub is integrated into the computer itself providing more than one USB port for attachment of a USB device. Similarly, an external USB hub may be connected to the PC to allow multiple USB devices to be connected to the external hub.

The third component is the function to be provided embodied in the USB device itself. A particular USB device may provide one or more functions that are added to the computer through the USB interface.

The interface of the USB is provided through a USB connector. The USB connector may include a length of cable having USB-type connectors on both ends, one USB-type connector configured for attachment to the host computer and the other for attachment to the USB device. Likewise, the USB connector may be partially integrated into the particular USB device with the appropriate USB connector end provided for plugging directly into a USB port of the host computer. For example, some USB flash memory devices are comprised of a housing which contains the flash memory storage media and a single USB-type connector extending directly from the housing for plugging the device into a USB port on a host computer. Whatever the form of the USB connector, the USB connector is provided with four lines including the VBUS, D+, D− and ground. The VBUS line is a voltage line which provides power, e.g., +5V, and may be employed to power some low voltage USB devices. In low-powered mode, USB devices may not draw more than 100 mA of current. In high-powered mode, the USB device can draw up to 500 mA of current without requiring an external power source. Thus, if a USB device requires more than 500 mA of current, then VBUS will be insufficient and an external power source (e.g., battery power or DC current from a DC adaptor connected to an AC outlet) must be provided. The D+ and D− lines are the data communication lines.

In some USB devices that require a power supply separate from VBUS, a problem may occur when voltage is applied to one of the data lines when VBUS is not present. Section 7.2.1 of the Universal Serial Bus Specification Revision 1.1 states, “They [devices] may not provide power to the pull-up resistor on D+/D− unless VBUS is present.” Some Power Macintosh G3 and G4 computers have been known to experience certain memory errors when a self-powered USB device that utilizes a USB pull-up resistor on one of the USB data lines is powered and connected to a host computer that has been turned off. Various computer failures have been identified including beeping, no video and no startup tone after power on, or the display of an error message stating that the built-in memory test has detected a problem. Thus, failures can shown up as a variety of boot problems including freezes, crashes, and tones.

The cause of such computer errors has been linked to a particular batch of dual inline memory modules (DIMMs) that have been packaged with certain Macintosh computers. These DIMMs have integrated circuits (ICs) that are sensitive to powering up from non-zero voltages. If the IC is sensitive to such voltages being present on the D+ or D− lines, of for example approximately +0.3V immediately prior to power up, an error within the DIMM may occur. For USB devices that employ a USB pull-up resistor on the D+ line, 3 or more volts may be applied to the D+ line immediately after power is applied to the USB device. When the USB cable of such a device is connected to the computer, enough current may trickle through to provide about a +0.3 volt source to the DIMM sockets. This voltage may result in one or more of the above-identified problems whether supplying current to the D+ or the D− line.

While +0.3 volts is typically not enough to power such DIMMs, DIMMs that are sensitive to such low voltages when the computer is off may be partially turned on prior to powering up of the computer causing the aforementioned problems. One suggested solution has been to replace the existing DIMMs of a computer with new ones that are less sensitive. Such a solution, however, may not be practical for many computer owners, especially if the computer in question is no longer under warranty, thus requiring the owner to purchase new DIMMs.

The present invention overcomes the foregoing disadvantages of the prior art by providing a solution that does not require modification to or replacement of parts on the host computer. More particularly, it would be advantageous to eliminate the voltage from the D+ or D− line of the USB device when the VBUS is not present to prevent voltage from the USB device from being applied to the memory of the host computer when the host computer is turned off, thus eliminating the associated computer errors as a result of the connection of the USB device to the host computer. These and other advantages will become apparent from a reading of the following summary and description of the illustrated embodiments in accordance with the principles of the present invention.

### SUMMARY OF THE INVENTION

Accordingly, the present invention provides a method and apparatus for a USB device that prevents a voltage from the USB device from being present on the data lines of the USB connection when the host computer to which the USB device is connected is turned off. More specifically, the present invention provides a method and apparatus for disabling a USB pull-up resistor on the USB device data line when VBUS is not present or at least at a relatively low voltage state (e.g., less than about 2.2V). The present invention also includes a method and apparatus for enabling the USB pull-up resistor on the USB device when the presence of VBUS is detected (e.g., when VBUS exceeds about 2.7V).

As previously discussed, while attached to a powered USB device, pulling up the USB D+ line (or the D− line as the case may be) from the USB device while VBUS (from the hub) is not present, may cause the host computer to hang, freeze or otherwise lock-up during a power cycle. The present invention resolves this issue by disabling the USB pull-up resistor if VBUS is not present (e.g., below about 2.2V). The method and apparatus of the present invention also includes enabling the USB pull-up resistor when VBUS exceeds a predetermined threshold (e.g., exceeds about 2.7V).

The circuit of the present invention employs a transistor to essentially turn the USB pull-up resistor on or off corresponding to the voltage on VBUS. The transistor is coupled between VBUS, a USB device voltage source (VCC) and an application specific integrated circuit (ASIC), the ASIC being a USB to AT Attachment Packet Interface (ATAPI) that enables the interface that supports mass storage devices such as CD-ROM drives, tape drives, and other data storage devices. [symbol] predefined window within which the voltage can fluctuate without

In order to provide a low cost solution, the transistor may be comprised of a bipolar junction transistor. While a comparable field effect transistor may also be employed, a bipolar junction transistor is typically a less expensive alternative.

The circuit allows a voltage to be applied to the input of the ASIC when VBUS is present and drops the voltage on the input of the ASIC when the voltage on VBUS drops below the threshold of the transistor. In addition, the circuit protects the ASIC input from the VBUS voltage and provides a current buffer to limit the flow of current to the ASIC.

In order to change the state of the USB pull-up resistor, an input buffer having TTL thresholds is provided. The input buffer produces a logic one or a logic zero to the ASIC depending upon the voltage. If the input buffer produces a logic one, the USB pull-up resistor will be enabled. If the input buffer produces a logic zero, the USB pull-up will be disabled. To prevent the circuit from rapidly cycling the USB pull-up resistor between an enabled state and a disabled state, the input buffer also provides hysteresis in the circuit. The hysteresis provides noise reduction in the voltage signal thereby conditioning the signal. Such conditioning essentially reduces the magnitude of or eliminates spikes and drops in the voltage that may otherwise trigger a change of state from a logic one to a logic zero or vise versa. Because voltages on VBUS may include noise that will cause slight variations in the actual voltage, the hysteresis provides a predefined window within which the voltage can fluctuate without changing the state of USB pull-up resistor. Thus, as the voltage on VBUS nears one of the TTL thresholds, transitions from a high state to a low state, the input buffer prevents the circuit from prematurely changing the state of the USB pull-up resistor from enabled to disabled or from disabled to enabled when the voltage at the input buffer is at or near one of the limits necessary for changing the state of the USB pull-up resistor. Thus, the input buffer provides a predefined window within which the voltage can fluctuate without changing the state of USB pull-up resistor.

The circuit of the present invention is configured to draw little current from VBUS, even if the power supply VCC is at 0V.

In addition, the circuit of the present invention protects the ASIC input, hereinafter ATA_EN,from the voltage on VBUS. This is accomplished by applying the voltage from the power supply to ATA_EN when VBUs is present. When the voltage on VBUS drops below a predetermined threshold, the voltage from the power supply on ATA_EN is essentially dropped to zero or at least a voltage that is well below the TTL threshold of the input buffer. The use of a transistor connected between VBUS, the USB power supply and ATA_EN provides control of the voltage on ATA_EN based upon the voltage of VBUS. VBUS is connected to the base of the transistor with the power supply of the USP device connected to the collector of the transistor. ATA_EN is connected to the emitter of the transistor with ATA_EN applying voltage to the input buffer. The input buffer is connected to the circuitry of the ASIC which includes an AND gate or equivalent circuitry. If sufficient voltage is applied to the input buffer to trigger a logic one from the input buffer, the AND gate or equivalent circuitry will enable the USB pull-up resistor and disable it if the input buffer produces a logic zero.

### BRIEF DESCRIPTION OF THE DRAWINGS

The drawings illustrate embodiments that are currently considered to be the best mode for carrying out the invention. However it is understood that the invention is not limited to the specific methods and circuitry disclosed.

Accordingly the foregoing summary as well as the following detailed description of the illustrated embodiments are better understood when read in conjunction with the following drawings.

FIG. 1 is a schematic diagram of a circuit for disabling a USC pull-up resistor connected to a data line of a USC device in accordance with the principles of the invention;

FIG. 2 is a schematic block diagram of a method of disabling a USC pull-up resistor in accordance with the principles of the invention,

FIG. 3 is a graph showing exemplary circuit voltages and currents;

FIG. 4 is a high level schematic block diagram of the invention; and

FIG. 5 is a matrix illustrating the tri-state characteristics of the circuitry of the present invention.

### DETAILED DESCRIPTION

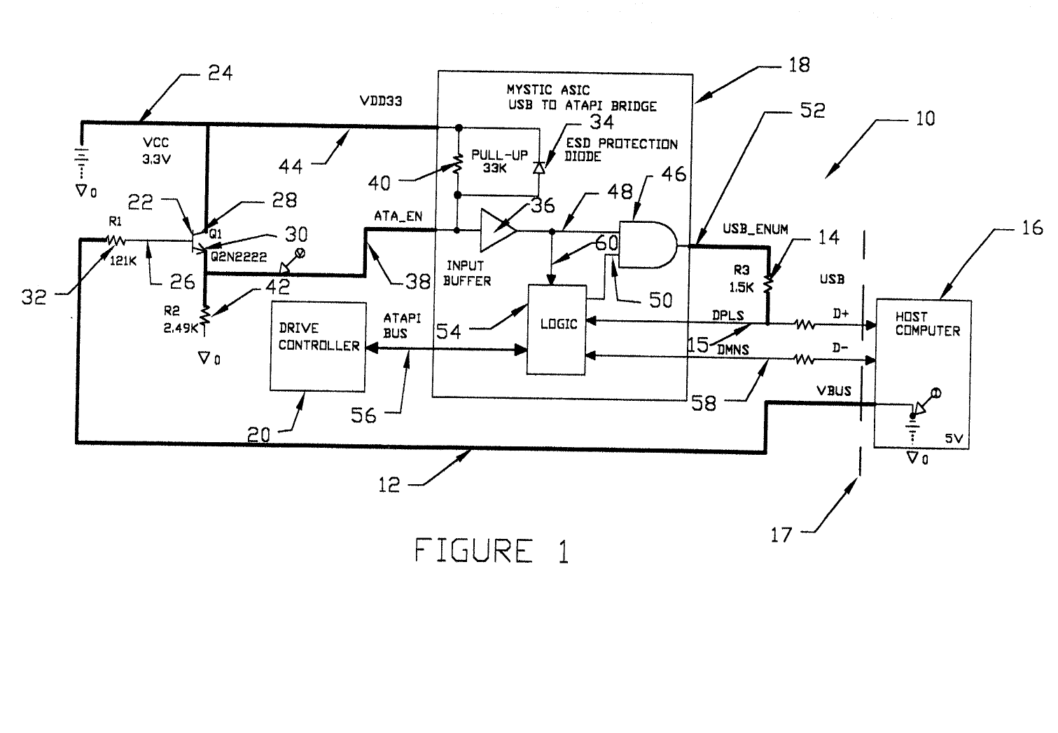

Referring to the drawings, there is shown in FIG. 1 a schematic diagram, representing a circuit generally indicated at 10, in accordance with the principles of the present invention. The circuit 10 is designed to detect the presence of a voltage on VBUS 12 in order to prevent current flow through a USB pull-up resistor 14 connected to a D+ line 15 of a USB device. The dashed line 17 represents the demarcation between the components that are included in the USB device and those that are contained in the host computer 16 to which the USB device is attached.

As previously discussed, if current is allowed to flow to the D− line 15 when VBUS 12 is not present, the host computer 16 may hang or freeze upon startup. Since VBUS 12 is provided by the host computer 16, an absence of a voltage on UBUS 12 is an indication that the host computer 16 may have been turned off or in the alternative the USB connection has been severed. For USB devices that have power consumption requirements that are greater than that provided by VBUS 12, the USB pull-up resistor 14 on the D+ line 15 needs to be disabled so as to not source power to VBUS when the host computer 16 is off. Utilizing the USB pull-up resistor 14, without regulation, may result in the aforementioned computer failures. Accordingly, the circuit 10 of the present invention controls the USB pull-up resistor 14 on the D+ line based upon the voltage of VBUS 12. When the voltage of VBUS 12 is high (i.e., exceeds a predetermined threshold), the USB pull-up resistor will be enabled. Once the voltage of VBUS 12 drops below a minimum limit, the USB pull-up resistor will be disabled. As such, the circuit 10 prevents current flow through the USB pull-up resistor 14 when VBUS 12 is not present or below the TTL limits of the circuit 10.

In the instant example, the circuit 10 includes a USB to ATAPI bridge application specific integrate circuit (ASIC) 18. The USB to ATAPI bridge ASIC 18 is employed to allow the host computer 16 to talk to a drive controller 20 of a mass storage device, such as a disk drive. The components of the circuit 10 provided to the left of the dashed line 17 are external to the host computer 16 and thus provided in the USB device. The ASIC 18 nominally operates at a voltage of about 3 volts. VBUS is typically at about 5 volts.

In order to provide the input 38 (hereinafter ATA_EN) to the ASIC 18 with an input voltage that is proportional to the voltage on VBUS 12, a transistor (Q1) 22 is placed between VBUS 12 and ATA_EN 38. The transistor 22 is an NPN bipolar junction transistor having a base 26 connected to VBUS 12. The collector 28 of the transistor 22 is connected to VCC 24 and the emitter 30 is connected to input ATA_EN 38 of the ASIC 18. In this arrangement, the transistor 22 has a common collector configuration and thus functions as an emitter follower.

The voltage on VBUS 12 is dropped by a first resistor (R1) 32 before VBUS 12 is applied to the base 26 of the transistor (Q1) 22. R1 32 drops the voltage to the base 26 of Q1 22 a sufficient amount to prevent current from flowing backwardly through the collector 28 to VCC 24 when VBUS 12 is higher than VCC 24. In the case where VCC 24 is zero, R1 32 limits the amount of current that can flow out of VBUS 12 and backward through the collector of Q1 22 to VCC 24. The circuit 10 also draws relatively little current from VBUS even when VCC is at 0 volts. With this configuration, that is, the collector 28 of Q1 22 connected to VCC 24 and the base voltage limited by R1 32, forward biasing of the internal ESD (electrostatic discharge) protection diode 34 is prevented, even with VBUS at a high state (e.g., 5.25V). Thus, the circuit 10 of the present invention is configured to protect the input ATA_EN 38 to the ASIC 18, as well as the ESD protection diode 34, from the voltage on VBUS 12 even when VBUS is high.

As the voltage on VBUS 12 changes, a proportional change in the voltage at ATA_EN 38 will occur. If the voltage on VBUS 12 is sufficient to turn on the Q1 22, then the voltage on ATA_EN 38 will be essentially that of the VCC 24, in this case 3.3 volts. Because there is a small drop in voltage across Q1 22 (e.g., 0.6 V), the actual voltage on ATA_EN 38 will be approximately 2.7 V. If the voltage on VBUS is not sufficient to turn on Q1 22, the circuit 10 is in the form of a voltage divider with the voltage on ATA_EN defined by the equation:

V_{ATA}_{_{—}}_{EN}=V_{CC}(R₂/(R₂+R_{internal pull-up}))

With the values of the circuit 10 shown in FIG. 1, the voltage on ATA_EN 38 would be about 0.23 volts.

The input buffer 36 is provided with TTL thresholds that produce either a logic one or a logic zero depending on the input voltage at the input buffer 54. For this input, limits are 0.8 V for logic zero and 2.0 V for logic one. Based upon the forgoing voltage values (i.e., 2.7 V if VBUS is high and 0.23 V if VBUS is low), the TTL thresholds of the input buffer 54 will be exceeded to change the logic state from one to zero and vise versa.

When the input voltage on ATA_EN 38 is at or near one of the TTL thresholds of the input buffer 54, noise in the voltage can prematurely cause a change in the logic state of the input buffer 58. The input buffer 36, however, has about 400 mV of hysteresis. The hysteresis provides noise reduction in the voltage signal to condition the signal. Such conditioning essentially reduces the magnitude of or eliminates spikes and drops in the voltage that may otherwise trigger a change of state from a logic one to a logic zero or vise versa. With such hysteresis, the input buffer 36 will normally provide a logic one if the voltage is above about 1.6 V. and a logic zero if the voltage is below about 1.2V. Thus, the 400 mV of hysteresis prevents the logic state of the circuit from changing when the voltage is between 1.2V and 1.6V.

As previously discussed, a logic zero is produced when Q1 22 is off and no emitter voltage is applied to ATA_EN 38. This is a result of the function of the transistor 22 when VBUS 12 is not present or at a relatively low voltage. That is, when VBUS 12 is low, the transistor Q1 22 is off and the current flows through the voltage divider in which case the voltage on ATA_EN 38 is low. Because VCC 24 is always present so long as the USB device is on, the voltage from VCC 24 (VDD 33) is dropped across the internal pull-up resistor 40 in the ASIC 18 when VBUS is low and Q1 is off. Also, the resistor (R2) 42 connected to the emitter 30 of Q1 22 has a significantly lower resistance than the internal pull-up resistor 40. The voltage of VCC is thus dropped to ground across the resistor 42.

Conversely, if VBUS 12 is high enough to activate the transistor 22, the voltage of VCC 24 is applied through the transistor 22 directly to the input buffer 38. Given the component values illustrated in FIG. 1 (e.g., VCC equals approximately 3.3 volts, VBUS equals approximately 5 volts, the transistor 22 (Q1) is a Q2N2222 transistor, R1 is a 121 kΩ resistor, R2 is a 2.49 kΩ resistor, R3 is a 1.5 kΩ resistor and the USB pull-up resistor R3 14. So long as VBUS 12 is high and the ASIC includes a 33 kΩ pull-up resistor 40), the voltage drop across R1, and the base emitter voltage drop of the transistor 22, a logic one will be detected by an AND gate 46 from the input buffer 36 if VBUS 12 is above about 2.2 V.

The representation of the AND gate 46 is provided for illustrative purposes to show a function of the circuit 10. This AND gate function, however, is provided by the ASIC 18 and its integrated circuitry logic. As such, reference herein to “the AND gate” generally refers to an AND gate function that in all practical purposes may be a more complex procedure employing the integrated circuitry of the ASIC 18 to determine the state of the logic from the input buffer in order to enable or disable the USB pull-up resistor 14.

The voltage, which has been conditioned by the input buffer 36, provides either a logic one or a logic zero to logic, represented by the AND gate 46, within the ASIC 18. In the illustration of the AND gate 46, two inputs lines 48 and 50 and an output 52 labeled as USB_ENUM are provided. Of course, the actual circuitry of the ASIC may be of a different configuration, but with similar function. With an AND gate 46, both input lines 48 and 50 must be at logic one in order for the logic level to pass through the AND gate to USB_ENUM 52. Thus, an AND gate only allows the digital signal through if both its inputs 48 and 50 are presenting a logic one to the AND gate 46. If either of the inputs to the AND gate 46 are a logic zero, then no signal is allowed to pass through to USB_ENUM 52, and thus R3 14 is disabled.

While one input 48 comes directly from the input buffer 36, the other input 50 is connected between the AND gate 46 and the logic circuit 54 of the ASIC 18. The logic circuit 54 can provide a logic one or a logic zero to the AND gate 46 through the input 50 in order to provide a second condition which must be present in order for current to flow through the AND gate 46 to the USB pull-up resistor R3 14. So long as VBUS 12 is high and VCC 24 is on, unless the logic 54 is configured to monitor some other condition, the input 50 to the AND gate 46 will be at logic one.

The logic 54 is essentially the brains of the USB to ATAPI ASIC 18. As previously discussed, the USB to ATAPI ASIC 18 allows the host computer 16 to talk to the ATAPI bus 56 of the drive controller 20 of the particular USB device to which the host computer 16 is connected and vise versa. The logic circuit 54 is connected to both the D+ line 15 and the D− line 58, which represent the data lines of a USB connection (e.g., a USB cable). The logic 54 can monitor ATA_EN through line 60.

Depending on the voltage of VBUS 12 and correspondingly the state of Q1 22, a different voltage will be seen at the input buffer 36. That is, if a base voltage of the transistor 22 is sufficiently high, current will flow through the emitter 30 and the resistor (R2) 42 causing a voltage rise in the input buffer 36. If not, the voltage of VCC 24 will be dropped across the internal pull-up resistor 40 and R2 42 to create a voltage of approximately 0.23 volts, well below the TTL threshold of the input buffer 36, resulting in a logic zero being detected by the circuit logic 54.

In order to prevent a false change in the logic state from a one to a zero or a zero to a one as a result of spikes or drops due to noise in the voltage, the input buffer 36 essentially conditions the signal to provide approximately 400 mV of hysteresis. That is, the input buffer 36 operates similarly to a thermostat of a furnace in which a certain threshold or limit must be reached before a change of state will occur. This prevents the circuit 10 from rapidly cycling from one state to another when the voltage is at or near one of the TTL thresholds.

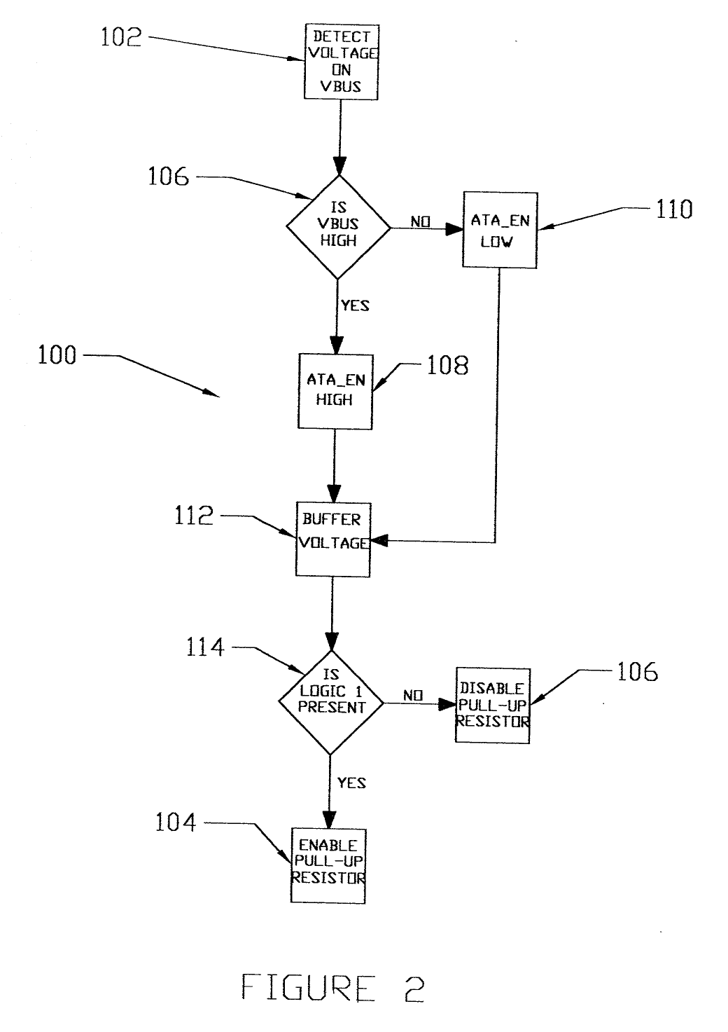

Referring now to FIG. 2, a schematic flow diagram of a method, generally indicated at 100, in accordance with the principles of the present invention is illustrated. The method 100 includes steps for detecting 102 the presence of a voltage on VBUS and enabling 104 or disabling 106 the USB pull-up resistor connected to one of the data lines of a USB device depending on the state of VBUS.

As such, the presence or lack thereof of a voltage on VBUS is detected 102, as with a transistor having a predetermined limit or threshold that when reached activates the transistor. Through such detection 102, it is determined 106 whether VBUS is high enough to reach the predetermined threshold. If VBUS is high (i.e., exceeds the threshold), then ATA_EN (i.e., the integrated circuit input) will be high 108. If VBUS is low, then ATA_EN will also be low 110. The voltage on ATA_EN will therefore be proportionate to the voltage on VBUS.

In order to condition ATA_EN and prevent undue cycling of the state of the USB pull-up resistor, the ATA_EN input voltage is buffered 112 to remove noise from the signal. Such conditioning of the ATA_EN signal provides hysteresis in the circuit 100 to ensure that the signal is truly high or truly low before the state of the circuit changes. That is, as VBUS nears one of the thresholds at which the state of the circuit will change, the hysteresis prevents the USB pull-up from toggling back-and-forth from enabled to disabled that may otherwise occur if noise is present in the signal.

Once the ATA_EN signal is buffered 112, the circuit 100 determines 114 through circuit logic whether ATA_EN represents a logic one or a logic zero. If ATA_EN represents a logic one, then the USB pull-up resistor will be enabled 104. If ATA_EN is low enough to represent a logic zero, then the USB pull-up resistor will be disabled 106. In practice, a logic one will be detected it VBUS is above about 2.7V and a logic zero will result of VBUS is below about 2.2V.

While the Universal Serial Bus Specification does not define the voltage at which VBUS must be before the USB pull-up is enabled, it is desirable not to enable the USB pull-up resistor when only a relatively small voltage is present on VBUS. Such small voltages may be the result of stray leakage currents on VBUS. The method and apparatus of the present invention prevents enabling of the USB pull-up resistor on the D+ or D− line, as the case may be, if VBUS is below about 2V. Of course, those of skill in the art will appreciate that various other thresholds and circuit limits may be attained by modifying the circuit components to accommodate such other thresholds or limits.

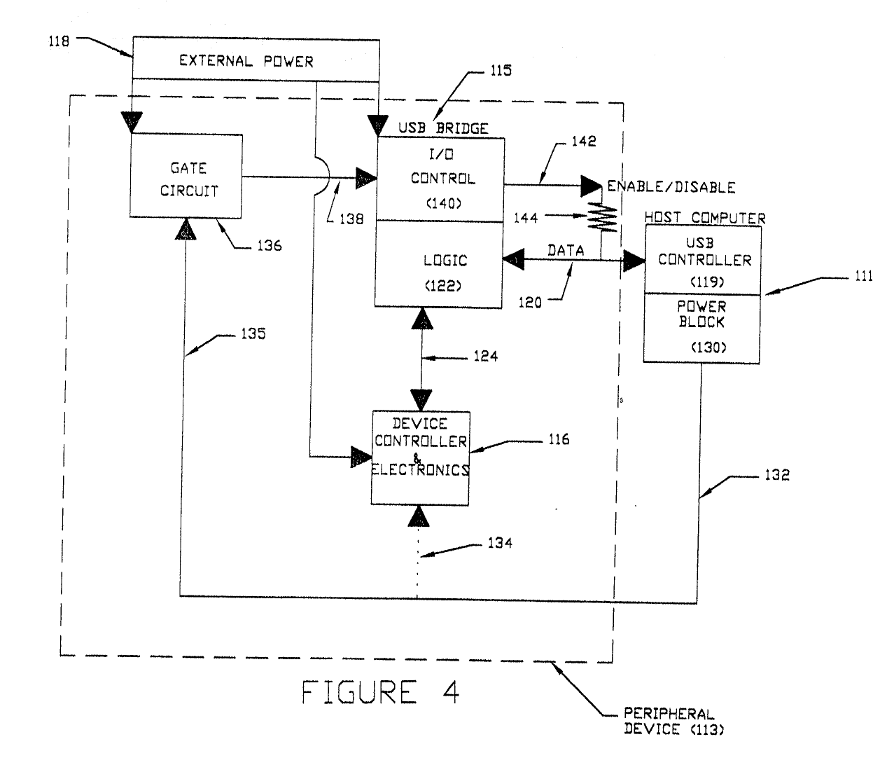

The block diagram of FIG. 4 provides a higher level schematic layout of the unique circuitry of the present invention which is particularly suited for peripheral devices such as a data storage drive which typically requires a higher external power supply 118 for normal operation A host computer 111 is coupled to a peripheral device 113 which incorporates a USB bridge unit 115 such as an ASIC which communicates through line 124 with the device controller & electronics 116 of the peripheral device. A USB controller 119 in the host computer sends and receives data and control messages across a data line 120 to a logic unit 122 incorporated in the USB bridge When the peripheral device is operating without any power from power block 130, the decreased voltage in line 135 causes gate circuit 136 to generate a proportionally lower voltage in inlet line 138 which is connected to the I/O Control circuitry 140 in the USB Bridge When such I/O Control circuitry sends a logic 0 through line 142, the pull-up resistor 144 is disabled thereby preventing any circuit aberrations that might otherwise occur

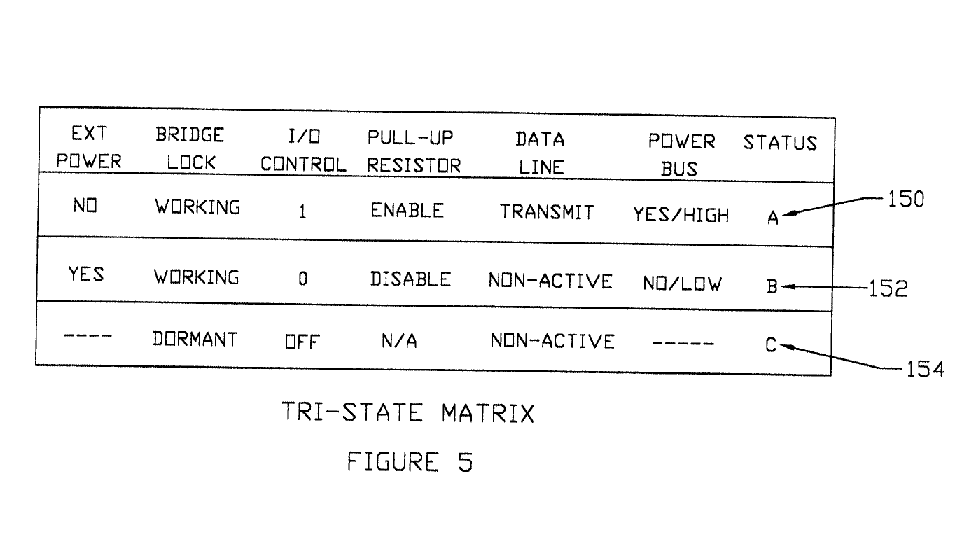

The matrix display of FIG. 5 illustrates the tri-state capabilities of the unique circuitry of the present invention utilizing a single input line to the USB Transfer Bridge For example the invention provides a first A state 150 wherein the I/O Control generates a logical 1 to enable the pull-up resistor when the host power bus is providing power to the peripheral, a second B state wherein the I/O Control generates a logical 0 when the host power bus is low (virtually off) to disable the pull-up resistor when the peripheral is self powered from an external power source, and a third C state wherein the I/O Control is “off” in order to allow diagnostic testing, etc of the USB Transfer Bridge

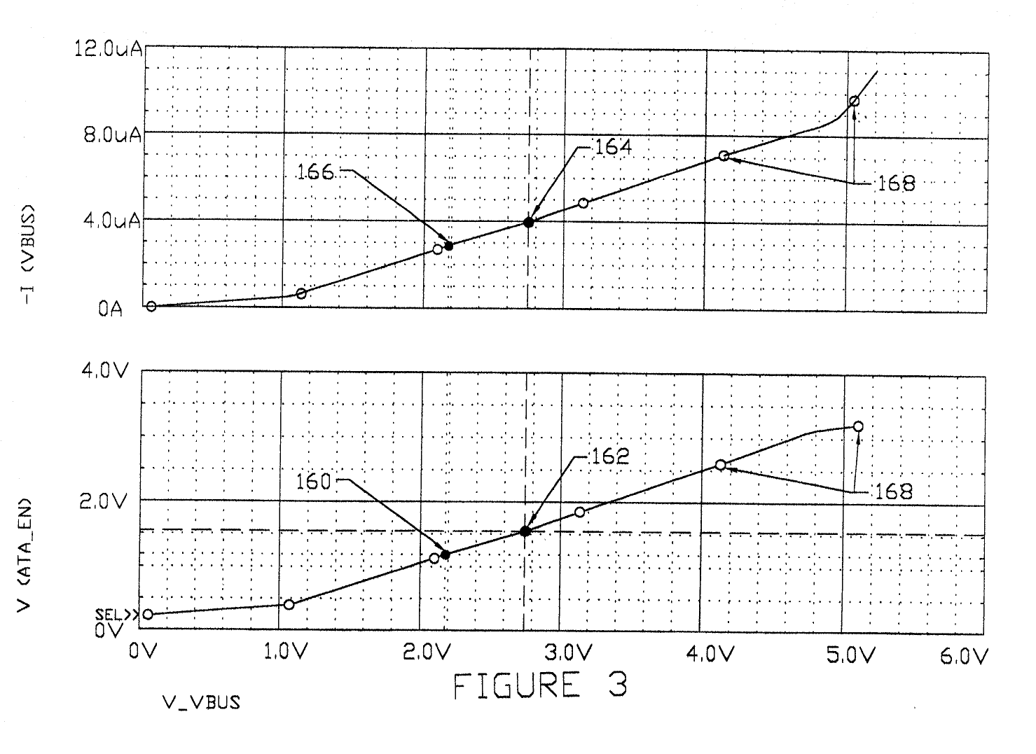

The two graphs of FIG. 3 show the relationship between the current on the host power line identified as —I(VBUS), the voltage on the host power line identified as V_VBUS and the proportional voltage identified as V(ATA_EN) on the transfer bridge input line It is to be noted that the data points 168 for the voltage and current changes define a function for the exemplary circuitry shown in FIG. 1. In that regard, the control gate circuit draws the current shown at 166 and generates an output voltage of approximately 1.2 volts when the V_VBUS decreases to a threshold of approximately 2.2 volts (see 160) thereby causing disabling of the pull-up resistor. On the other hand the control gate circuit draws the current shown at 164 and generates an output voltage of approximately 1.6 volts when the V_VBUS increases to a different threshold or approximately 27 volts (see 162) thereby causing enabling of the pull-up resistor.

While the methods and apparatus of the present invention have been described with reference to certain preferred embodiments to illustrate what is believed to be the best mode of the invention, it is contemplated that upon review of the present invention, those of skill in the art will appreciate that various modifications and combinations may be made to the present embodiments without departing from the spirit and scope of the invention as recited in the claims. The claims provided herein are intended to cover such modifications and combinations and all equivalents thereof. Reference herein to specific details of the illustrated embodiments is by way of example and not by way of limitation.

What is claimed is:

1. An circuit for disabling a pull-up resistor connected to a data line of a universal serial bus device, comprising:
a universal serial bus connection comprised of at least one power source and at least two data lines;
an integrated circuit connected to the at least two data lines and having an input;
an external power supply connected to the integrated circuit;
at least one transistor interconnected between VBUS and the input, the power source and the integrate circuit for controlling voltage to the input of the integrated circuit corresponding to the voltage of VBUS; and
a pull-up resistor connected between the application specific integrated circuit and a data line of a USB connection, the state of the pull-up being controlled by the application specific integrated circuit depending upon the voltage on the input.

2. The circuit of claim 1, wherein said at least one transistor has a base, a collector and an emitter, the power source connected to the base, the external power supply connected to collector and the emitter connected to the integrated circuit.

3. The circuit of claim 2, further including at least one first resistor interposed between the power source and the base of the at least one transistor to drop the voltage of the power source before being applied to the base of the at least one transistor.

4. The circuit of claim 3, further including a second resistor connected to ground and to the emitter of the at least one transistor and a first pull-up resistor connected between the external power supply and the emitter of said at least one transistor.

5. The circuit of claim 4, wherein the power source is at approximately 5 volts, the external power supply is at approximately 3.3 volts, the first resistor is an approximately 121 kΩ resistor, the second resistor is an approximately 2.49 kΩ resistor, and the transistor is a Q2N2222 transistor.

6. The circuit of claim 1, wherein said resistor comprises an NPN bipolar junction transistor.

7. The circuit of claim 1, further including circuitry for providing hysteresis to filter noise from the external power supply.

8. The circuit of claim 7, wherein the circuitry for providing hysteresis comprises an input buffer through which voltage on the input is buffered.

9. The circuit of claim 4, further including an electrostatic protection diode in parallel with the first pull-up resistor, the transistor protecting the electrostatic protection diode from voltage from the power source.

10. The circuit of claim 1, wherein relatively little current is drawn from the power source when the external power supply is at zero.

11. The circuit of claim 1, further including a logic circuit within the integrated circuit.

12. The circuit of claim 11, wherein said logic circuit is a universal serial bus to ATAPI bridge.

13. The circuit of claim 11, wherein said application specific integrated circuit provides an AND gate function for allowing current to flow to the pull-up resistor if the voltage on the input represents a logic one.

14. The circuit of claim 11, wherein a logic one will be present if the input is above about 2.7 volts and a logic zero will be present if the input is below about 2.2 volts.

15. A method of disabling a pull-up resistor connected to a data line of a universal serial bus device comprising a universal serial bus connection comprised of a power source, at least two data lines, a pull-up resistor connected to one of the at least two data lines, an external power supply and an integrated circuit having an input, the method comprising:
detecting the presence of a voltage of the at least one power source;
applying a voltage to the input of the integrated circuit that is proportionate to the voltage on the at least one power supply;
determining if the voltage on the input represents a logic one or a logic zero; and
enabling the pull-up resistor if the voltage on the input represents a logic one and disabling the pull-up resistor if the voltage on the input represents a logic zero.

16. The method of claim 15, further including preventing the pull-up resistor from alternating from enabled to disabled due to noise in a signal from the external power supply.

17. The method of claim 16, further including buffering the external power supply voltage to provide hysteresis for filtering noise.

18. The method of claim 15, further including providing at least one transistor interconnected between the power source and the integrate circuit for controlling voltage on the input of the integrated circuit.

19. The method of claim 18, further including dropping the voltage of the power source before applying the voltage to the base of the at least one transistor.

20. The method of claim 15, further including configuring the integrated circuit as a universal serial bus to ATAPI bridge.

21. The method of claim 18, further including providing the integrated circuit with an electrostatic protection diode and protecting the electrostatic protection diode with the at least one transistor.

22. The method of claim 15, further including drawing relatively little current from the power source when the external power supply is at zero.

23. The method of claim 15, wherein said determining if the voltage on the input represents a logic one or a logic zero is performed by providing an AND gate function between the input of the integrated circuit and the pull-up resistor such that the AND gate function will allow current to flow through the pull-up resistor if a logic one is present.

24. The circuit of claim 23, further including enabling the pull up resistor if the power source is above about 2.7 volts and disabling the pull-up resistor if the power source is below about 2.2 volts.

25. A method for preventing malfunctions in a data transmission system which transmits digital signals along a data bus between a host computer and a peripheral device wherein the peripheral device may receive power from the host computer or alternatively from an external power source, comprising
interconnecting a transfer bridge circuit between the host computer and the peripheral device, the bridge circuit having a first interface between the bridge circuit and the host computer, a second interface with a protective circuit, and a third interface with the peripheral device electronics,
providing a pull-up resistor connected in a separate line between the first interface and the data bus,
sensing whether power is being supplied along a power line from the host computer to the peripheral device, and if appreciable power is not detected in the host power line, then
deactivating the pull-up resistor to prevent any malfunction from occurring.

26. The method of claim 25 wherein said deactivating occurs upon sensing that a voltage in the host power line is below a predetermined first threshold level

27. The method of claim 26 which further includes activating the pull-up resister upon sensing that a voltage in the host power line is above a predetermined second threshold level.

28. The method of claim 27 wherein said second threshold level is higher than said first threshold level

29. The method of claim 25 which further includes providing an input line to the second interface from an electronic gate coupled to the power line, and incorporating a logic circuit in the bridge circuit connected to the second interface, and generating a logical I/O control signal from the logic circuit to cause the enabling or disabling of the pull-up resistor.

30. The method of claim 29 wherein said input line is capable of creating three different states of operation in the bridge circuit, including a first state when an external power supply is connected to the peripheral device with the pull-up resistor disabled.

31. The method of claim 30 wherein the data bus incorporates two transmission lines each capable of transmitting data at different rates, respectively, and including a second state when the host computer supplies power to the peripheral device with the pull-up resistor enabled
